(19) United States
(12) Patent Application Publication
(10) Pub. No.: US 2014/0374698 A1
(43) Pub. Date: Dec. 25, 2014

(54) LIGHT EMITTING DIODE CHIP AND METHOD FOR MANUFACTURING SAME

(71) Applicant: Hon Hai Precision Industry Co., Ltd., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/064,208

(22) Filed: Oct. 28, 2013

(30) Foreign Application Priority Data
Jun. 25, 2013 (TW) 102122599

(51) Int. Cl. H01L 33/06; H01L 33/00; H01L 33/62; H01L 33/32

(52) U.S. Cl. CPC H01L 33/06; H01L 33/32; H01L 33/0075; H01L 33/62
USPC 257/13; 438/26

(57) ABSTRACT

A light emitting diode chip includes a substrate and a first conductive layer formed on the substrate. The first conductive layer includes a plurality of P-type AlInGaN layers and a plurality of graphenel layers alternately stacked on each other. A P-type AlInGaN layer, an active layer and an N-type AlInGaN layer are formed on the first conductive layer in sequence. A second conductive layer is formed on the N-type AlInGaN layer. A first electrode is electrically connected to the first conductive layer and a second electrode is electrically connected to the second conductive layer.

### BACKGROUND

1. Technical Field

The disclosure generally relates to a light emitting diode chip and a method for making the light emitting diode chip.

2. Description of Related Art

In recent years, due to excellent light quality and high luminous efficiency, light emitting diodes (LEDs) have increasingly been used as light sources of illumination devices for substituting for incandescent bulbs, compact fluorescent lamps and fluorescent tubes.

In order to improve light extracting efficiency of the light emitting diode, how to decrease a starting voltage and inner resistance of the light emitting diode chip in order to reduce heat generation during operation of the light emitting diode chip has been endeavored by the industry. Particularly, how to reduce the inner resistance of the light emitting diode chip is a problem that the industry always wants to solve.

What is needed, therefore, is a light emitting diode chip and a method for manufacturing the light emitting diode chip to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of a light emitting diode chip in accordance with a first embodiment of the present disclosure.

FIG. 2 is a cross sectional view of a first conductive layer in FIG. 1.

FIG. 3 is a cross sectional view of a second conductive layer in FIG. 1.

FIGS. 4-8 are different cross sectional views showing different steps of a method for manufacturing the light emitting diode chip in FIG. 1.

FIG. 9 is a cross sectional view of a light emitting diode chip in accordance with a second embodiment of the present disclosure.

FIGS. 10-15 are different cross sectional views showing different steps of a method for manufacturing the light emitting diode chip in FIG. 9.

### DETAILED DESCRIPTION

Embodiments of a light emitting diode chip and a method for manufacturing the light emitting diode chip will now be described in detail below and with reference to the drawings.

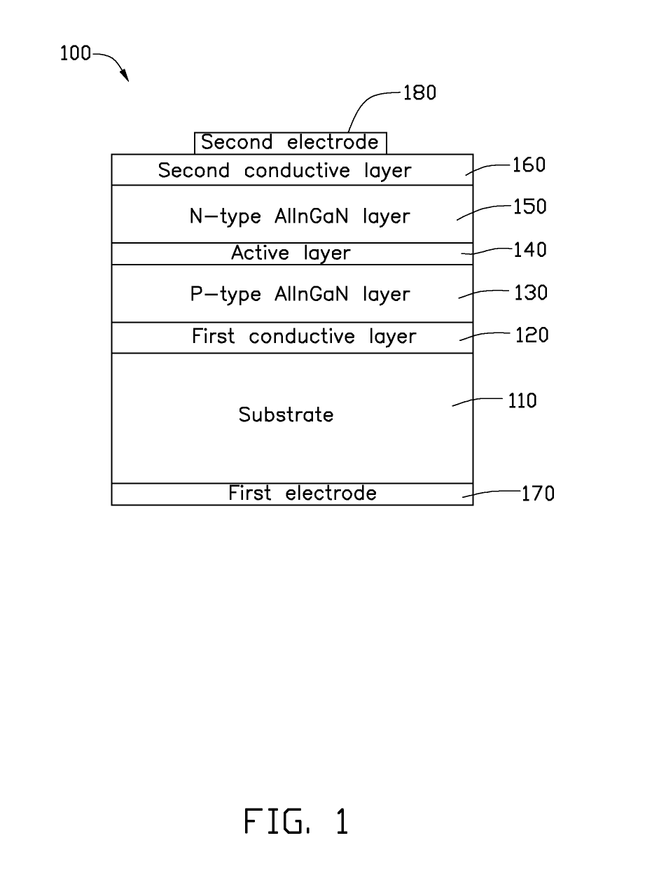

Referring to FIG. 1, a light emitting diode chip 100 in accordance with a first embodiment is provided. The light emitting diode chip 100 includes a substrate 110, a first conductive layer 120 formed on the substrate 110, a P-type AlInGaN layer 130, an active layer 140 and an N-type AlInGaN layer 150 formed on the first conductive layer 120, and a second conductive layer 160 formed on the N-type AlInGaN layer 150. The active layer 140 can be single quantum well structure or multiple quantum well structure, which is made of InGaN/GaN or InGaN/AlGaInN.

The substrate 110 is electrically and thermally conductive. In this embodiment, the substrate 110 is made of a material selected from Cu, Al, Fe, Ni and alloys thereof.

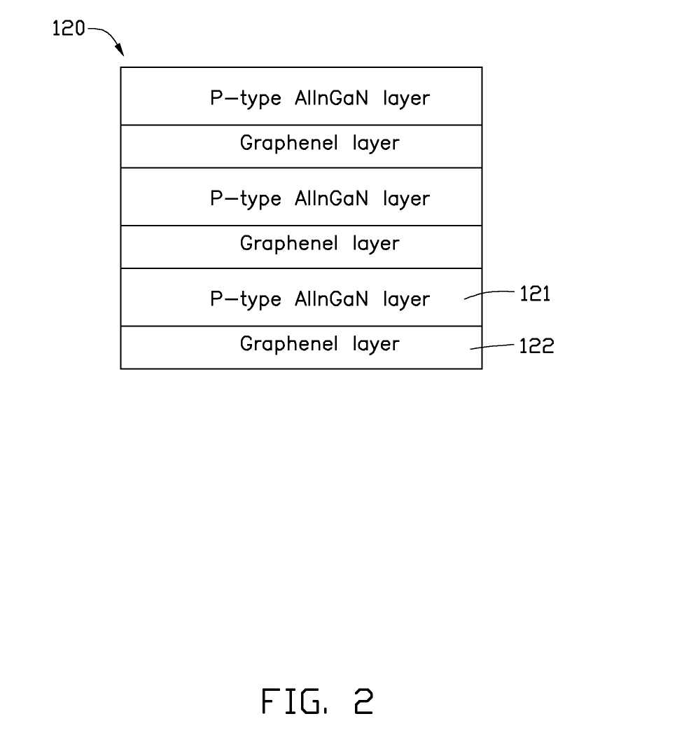

Referring to FIG. 2, the first conductive layer 120 includes a plurality of P-type AlInGaN layers 121 and a plurality of graphenel layers 122 alternately stacked on each other. Since the graphenes of the graphenel layers 122 each have an electronic resistance about 10⁻⁶ Ω*cm and an electron mobility about 15000 cm²/Vsec, the first conductive layer 120 will have a relatively low electronic resistance. Therefore, heat generated by the light emitting diode chip 120 is reduced and a light extracting efficiency of the light emitting diode chip 120 is improved. Preferably, the graphenel layers 122 each can be consisted of a single graphene or multiple graphenes stacked together.

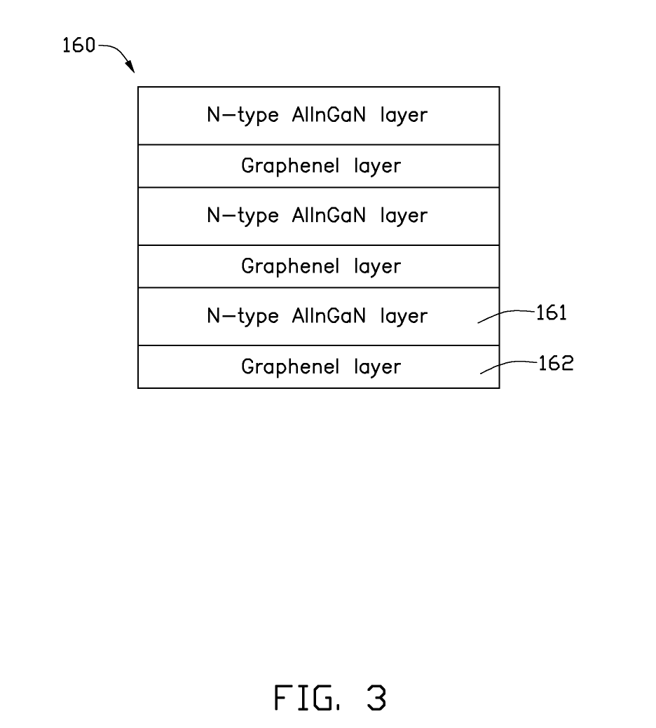

Referring to FIG. 3, the second conductive layer 160 includes a plurality of N-type AlInGaN layer 161 and a plurality of graphenel layers 162 alternately stacked on each other. Therefore, the second conductive layer 160 also has a relatively low electronic resistance. Heat generated by the light emitting diode chip 120 is reduced and a light extracting efficiency of the light emitting diode chip 120 is improved.

The light emitting diode chip 100 can further include a first electrode 170 and a second electrode 180. The first electrode 170 is electrically connected with the first conductive layer 120. The second electrode 180 is electrically connected with the second conductive layer 160. In this embodiment, the first electrode 170 is formed on a bottom surface of the substrate 110 opposite to the first conductive layer 120. Since the substrate 110 is conductive, the first electrode 170 is electrically connected with the first conductive layer 120 through the substrate 110. The second electrode 180 is formed on a top surface of the second conductive layer 160 and electrically connected with the second conductive layer 160. The light emitting diode chip 100 can be manufactured in following steps.

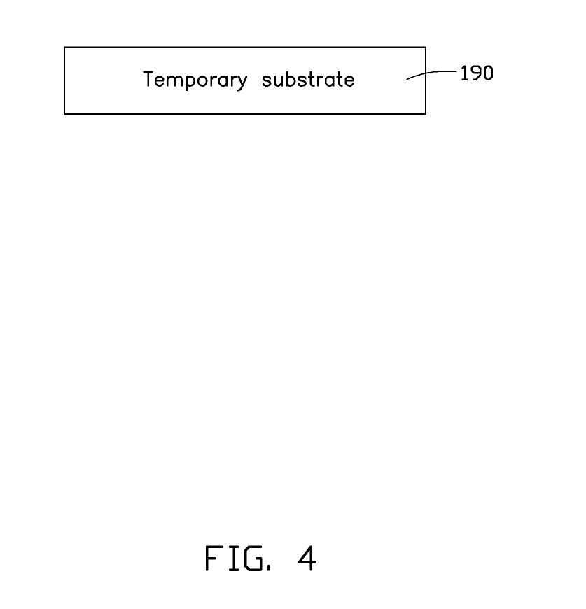

Referring to FIG. 4, a temporary substrate 190 is provided.

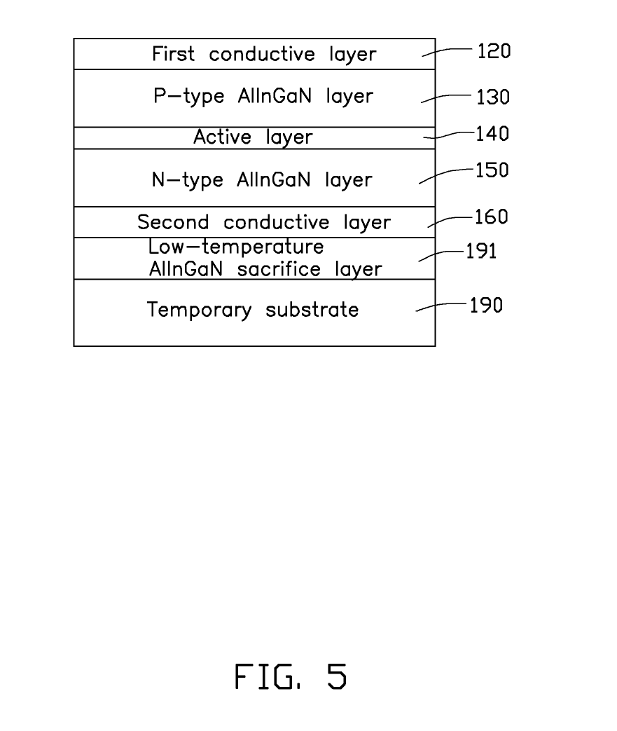

Referring to FIG. 5, a low-temperature AlInGaN sacrifice layer 191, a second conductive layer 160, an N-type AlInGaN layer 150, an active layer 140, a P-type AlInGaN layer 130 and a first conductive layer 120 are formed on the temporary substrate 190 in sequence. The first conductive layer 120 includes a plurality of P-type AlInGaN layers 121 and a plurality of graphenel layers 122 alternately stacked on each other.

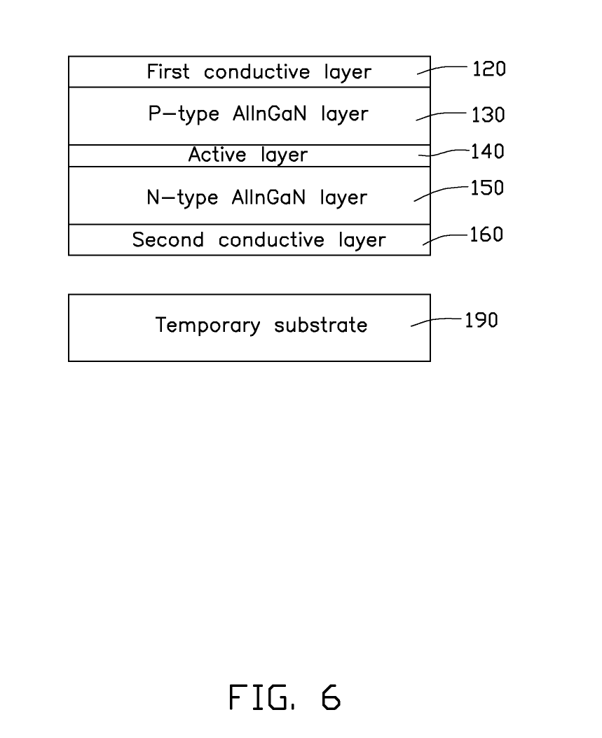

Referring to FIG. 6, the low-temperature AlInGaN sacrifice layer 191 is removed to separate the temporary substrate 190 from the second conductive layer 160. The low-temperature AlInGaN sacrifice layer 191 can be removed by ultraviolet light, laser assisted etching, or thermal etching.

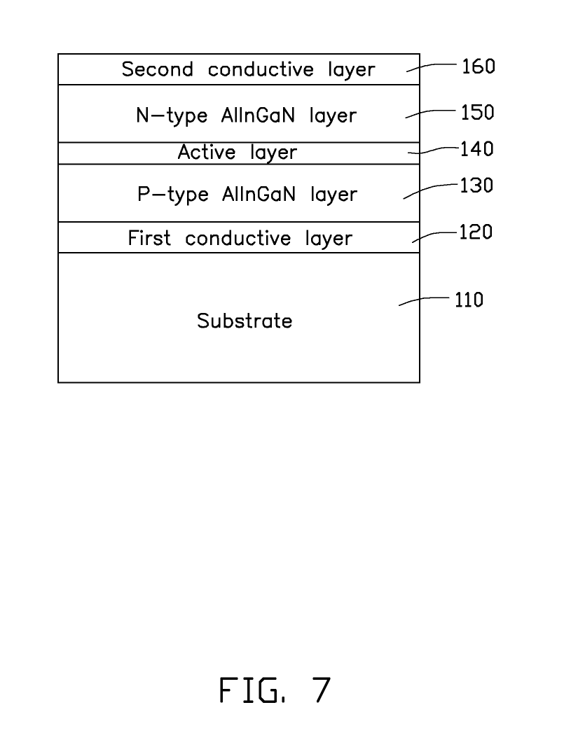

Referring to FIG. 7, a conductive substrate 110 is bonded to a bottom surface of the first conductive layer 120. The conductive substrate 110 is made of metallic materials such as Cu, Al, Fe, Ni and alloys thereof. Alternatively, the conductive substrate 110 can be made of semiconductor, such as silicon (Si).

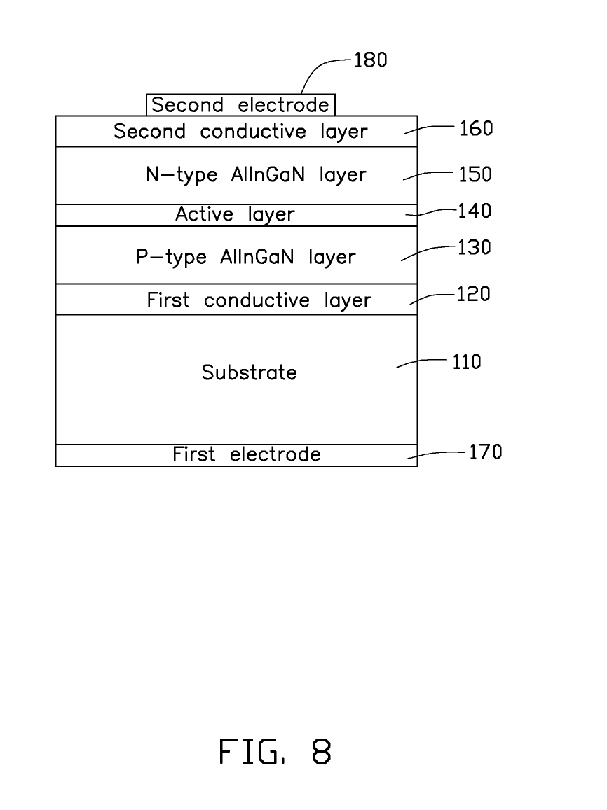

Referring to FIG. 8, a first electrode 170 is formed on a bottom surface of the conductive substrate 110 opposite to the first conductive layer 120. A second electrode 180 is formed on a top surface of the second conductive layer 160.

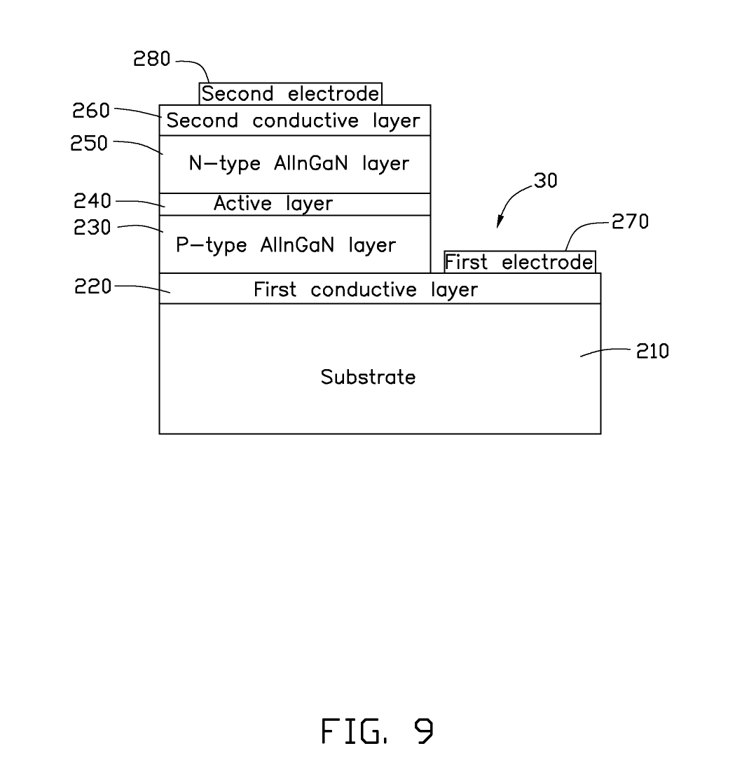

Referring to FIG. 9, a light emitting diode chip 200 in accordance with a second embodiment is provided. The light emitting diode chip 200 includes a substrate 210, a first conductive layer 220 formed on the substrate 210, a P-type AlInGaN layer 230, an active layer 240, an N-type AlInGaN layer 250 formed on the first conductive layer 220, and a second conductive layer 260 formed on the N-type AlInGaN layer 250.

The substrate 210 can be made of semiconductor materials such as silicon, or made of metallic materials such as Cu, Al, Fe, Ni and alloys thereof, or made of electrically insulating material such as sapphire. The first conductive layer 220 includes a plurality of P-type AlInGaN layers and a plurality of graphenel layers alternately stacked on each other. The second conductive layer 260 includes a plurality of N-type AlInGaN layers and a plurality of graphenel layers alternately stacked on each other. The active layer 240 can be single quantum well structure or multiple quantum well structure, which is made of InGaN/GaN or InGaN/AlGaInN.

Different from the first embodiment, the light emitting diode chip 200 includes an etched platform 30. The etched platform 30 extends from the second conductive layer 260 to the first conductive layer 220 to expose a part of the first conductive layer 220. The light emitting diode chip 200 further includes a first electrode 270 and a second electrode 280. The first electrode 270 is formed on the etched platform 30 and electrically connects with the first conductive layer 220. The second electrode 280 is formed on an upper surface the second conductive layer 260.

The light emitting diode chip 200 can be manufactured in following steps.

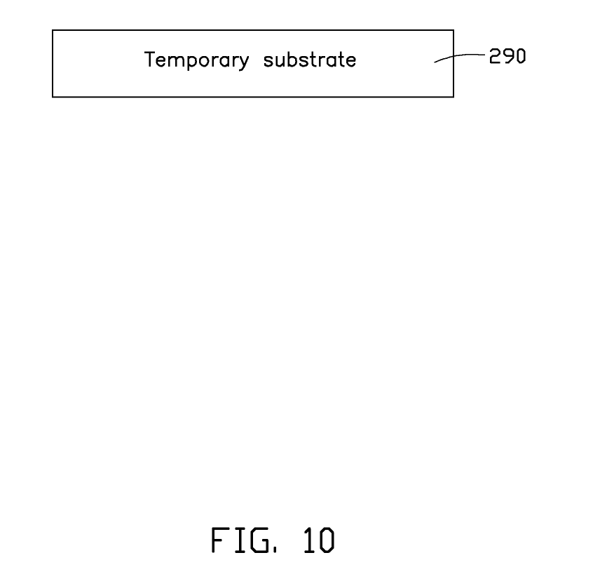

Referring to FIG. 10, a temporary substrate 290 is provided.

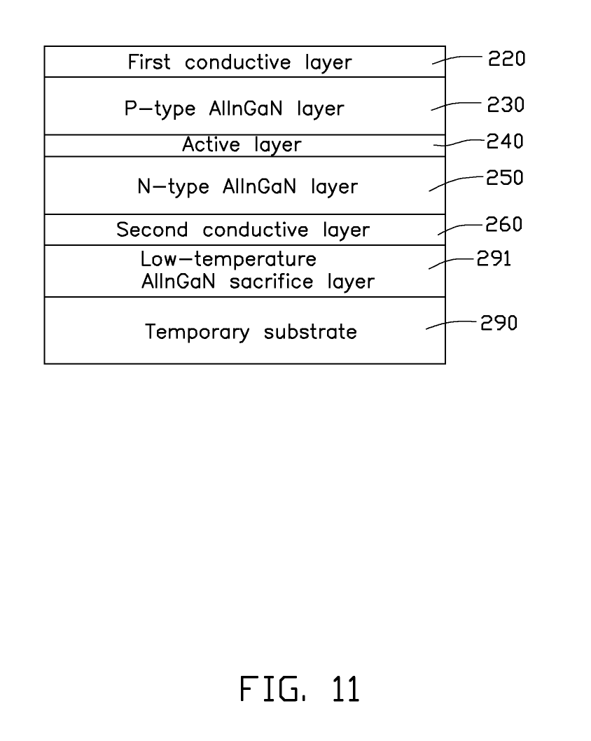

Referring to FIG. 11, a low-temperature AlInGaN sacrifice layer 291, a second conductive layer 260, an N-type AlInGaN layer 250, an active layer 240, a P-type AlInGaN layer 230 and a first conductive layer 220 are formed on the temporary substrate 290 in sequence. The first conductive layer 220 includes a plurality of P-type AlInGaN layers and a plurality of graphenel layers alternately stacked on each other. The second conductive layer 260 includes a plurality of N-type AlInGaN layers and a plurality of graphenel layers alternately stacked on each other.

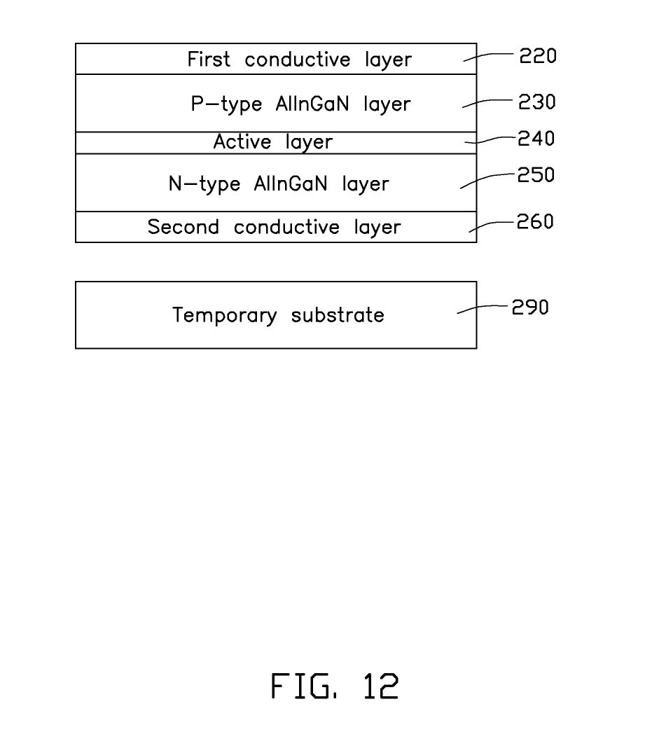

Referring to FIG. 12, the low-temperature AlInGaN sacrifice layer 291 is removed to separate the temporary substrate 290 from the second conductive layer 260. The low-temperature AlInGaN sacrifice layer 291 can be removed by ultraviolet light illumination, laser assisted etching, or thermal etching.

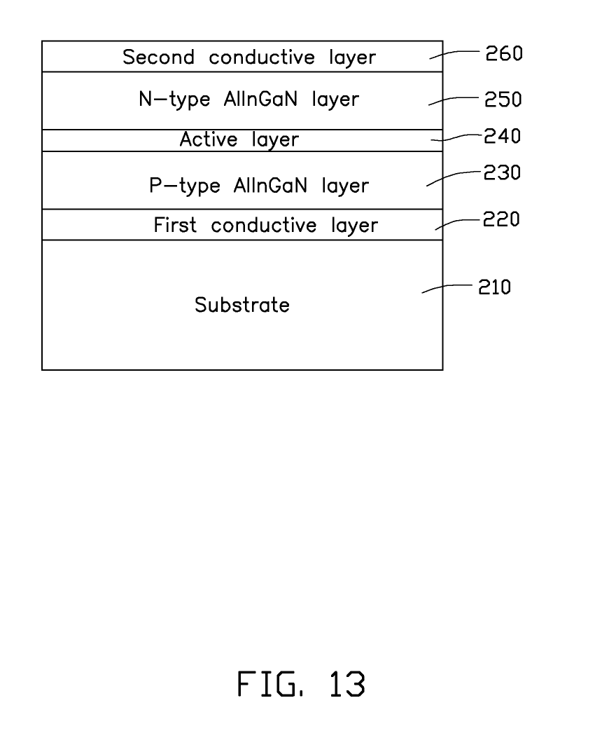

Referring to FIG. 13, a substrate 210 is bonded to a bottom surface of the first conductive layer 220. The substrate 210 can be electrically conductive or electrically insulating.

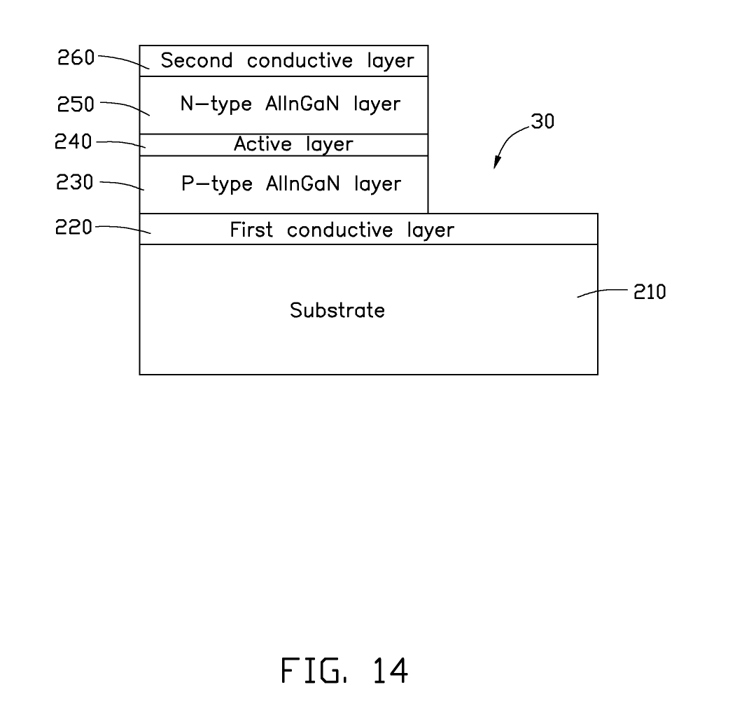

Referring to FIG. 14, an etched platform 30 is formed by etching away a part of each of the second conductive layer 160, the N-type AlInGaN layer 150, the active layer 140 and the P-type AlInGaN layer 130. The etched platform 30 extends from the second conductive layer 260 to the first conductive layer 220 to expose a part of the first conductive layer 220.

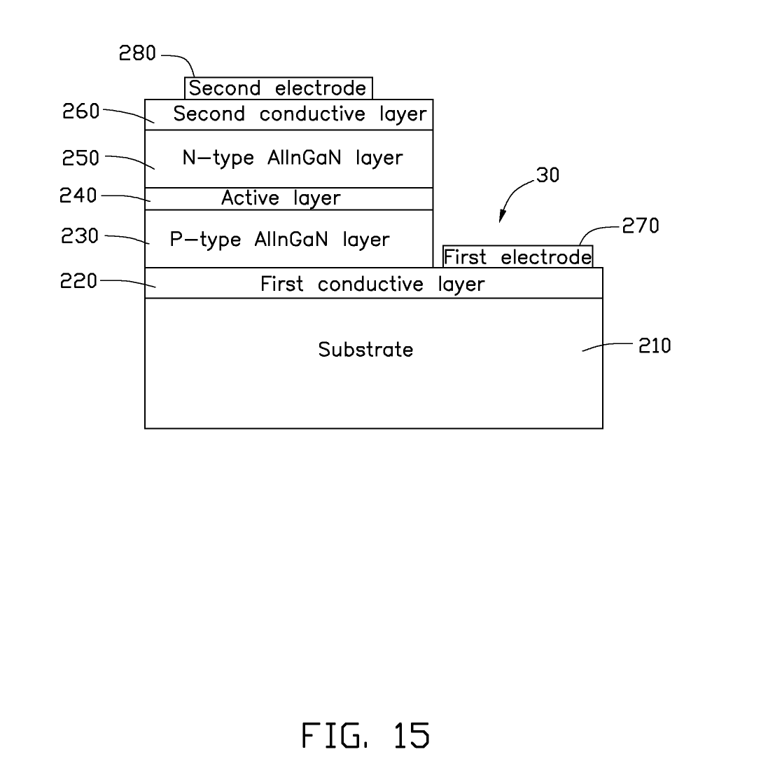

Referring to FIG. 15, a first electrode 270 is formed on the exposed surface of the first conductive layer 220. A second electrode 280 is formed on an upper surface of the second conductive layer 260.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode chip, comprising:
a substrate;
a first conductive layer formed on the substrate, the first conductive layer comprising a plurality of P-type AlInGaN layers and a plurality of graphenel layers alternately stacked on each other;
a P-type AlInGaN layer, an active layer, a N-type AlInGaN layer formed on the first conductive layer in sequence; and
a second conductive layer formed on the N-type AlInGaN layer.

2. The light emitting diode chip of claim 1, wherein the second conductive layer comprises a plurality of N-type AlInGaN layers and a plurality of graphenel layers alternately stacked on each other.

3. The light emitting diode chip of claim 1, wherein each of the graphenel layers comprises a single graphene or multiple graphenes stacked together.

4. The light emitting diode chip of claim 1, wherein the light emitting diode chip further comprises a first electrode and a second electrode, the first electrode is electrically connected with the first conductive layer, and the second electrode is electrically connected with the second conductive layer.

5. The light emitting diode chip of claim 4, wherein the substrate is conductive, the first electrode is formed on a bottom surface of the substrate opposite to the first conductive layer, the second electrode is formed on a top surface of the second conductive layer.

6. The light emitting diode chip of claim 5, wherein the substrate is made of a material selected from Cu, Al, Fe, Ni and alloys thereof.

7. The light emitting diode chip of claim 1, wherein the active layer is single quantum well structure or multiple quantum well structure.

8. The light emitting diode chip of claim 4, wherein an etched platform is formed on the light emitting diode chip, the etching platform extends from the second conducive layer to the first conductive layer to expose a part of the first conductive layer, the first electrode is formed on the etched platform and electrically connected with the first conductive layer, the second electrode is electrically connected with the second conductive layer.

9. A method for manufacturing a light emitting diode chip, comprising following steps:
providing a temporary substrate;
forming a low-temperature AlInGaN sacrifice layer, a second conductive layer, an N-type AlInGaN layer, an active layer, a P-type AlInGaN layer and a first conductive layer on the temporary substrate in sequence, the first conductive layer comprising a plurality of P-type AlInGaN layers and a plurality of graphenel layers alternately stacked on each other;
removing the low-temperature AlInGaN sacrifice layer to separate the temporary substrate from the second conductive layer;
attaching a conductive substrate to the first conductive layer; and
forming a first electrode on a bottom surface of the conductive substrate opposite to the first conductive layer, and forming a second electrode on a top surface of the second conductive layer.

10. The method of claim 9, wherein the second conductive layer comprises a plurality of N-type AlInGaN layers and a plurality of graphenel layers alternately stacked on each other.

11. The method of claim 9, wherein the conductive substrate is made of semiconductor material.

12. The method of claim 9, wherein the conductive substrate is made of metallic material selected from Cu, Al, Fe, Ni and alloys thereof.

13. A method for manufacturing a light emitting diode chip, comprising following steps:
providing a temporary substrate;
forming a low-temperature AlInGaN sacrifice layer, a second conductive layer, an N-type AlInGaN layer, an active layer, a P-type AlInGaN layer and a first conductive layer on the temporary substrate in sequence, the first conductive layer comprising a plurality of P-type AlInGaN layers and a plurality of graphenel layers alternately stacked on each other;
removing the low-temperature AlInGaN sacrifice layer to separate the temporary substrate from the second conductive layer;
bonding a substrate to the first conductive layer; and
forming a first electrode to electrically connect with the first conductive layer and forming a second electrode to electrically connect with the second conductive layer.

14. The method of claim 13, wherein the second conductive layer comprises a plurality of N-type AlInGaN layers and a plurality of graphenel layers alternately stacked on each other.

15. The method of claim 13, wherein after the step of bonding a substrate to the first conductive layer, an etching step is proceeded with to etch away a part of each of the second conductive layer, the N-type AlInGaN layer, the active layer and the P-type AlInGaN layer to expose a part of the first conductive layer.

16. The method of claim 15, wherein the substrate is electrically conductive or electrically insulating.

17. The method of claim 16, wherein the substrate is electrically insulating.

18. The method of claim 17, wherein the substrate is made of sapphire.

19. The method of claim 16, wherein the first electrode is attached to the exposed part of the first conductive layer, and the second electrode is attached to a surface of the second conductive layer away from the N-type AlInGaN layer.

20. The method of claim 13, wherein the substrate is conductive and the first electrode is attached to a surface of the substrate away from the first conductive layer, and the second electrode is attached to a surface of the second conductive layer away from the N-type AlInGaN layer.
